(19) United States
(12) Patent Application Publication
(10) Pub. No.: US 2003/0184986 A1
(43) Pub. Date: Oct. 2, 2003

(54) Circuit board and electronic device, and method of manufacturing same

(75) Inventors: Tasao Soga, Hitachi (JP); Hanae Hata, Yokohama (JP); Toshiharu Ishida, Fujisawa (JP); Masahide Okamoto, Yokohama (JP); Syougo Senoo, Yokohama (JP); Toshiyuki Kagami, Kawasaki (JP); Akihiro Sakashita, Takayama (JP)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hitachi, Ltd., Tokyo (JP)

(21) Appl. No.: 10/371,303

(22) Filed: Feb. 20, 2003

(30) Foreign Application Priority Data
Mar. 29, 2002 (JP) 2002-093546

(51) Int. Cl. H05K 7/10

(52) U.S. Cl. 361/767

(57) ABSTRACT

A circuit board has a first electrode and a second electrode connected with respective electrodes of a chip and a first insulating layer with openings provided at respective positions corresponding to the first electrode and the second electrode. The openings of the first insulating layer are shaped so that the first insulating layer does not cover at least a region below the chip on the peripheral edges of the first and second electrodes.

### BACKGROUND OF THE INVENTION

This invention relates to a circuit board, an electronic device and a method of manufacturing them. More particularly, this invention relates to a circuit board for solder connections using a lead-free solder alloy as a substitute for lead-tin eutectic solder, an electronic device having lead-free solder connections, and a method of manufacturing them.

Previously, for a circuit board having electronic parts, such as integrated circuits (chips), a structure is created by mounting the chips on the board. When the electrodes of the chips are connected to the conducting traces or regions of the substrate, the chips are pressed to the substrate after application of a solder paste printed on the substrate. Solder is supplied to a wiring pattern on a circuit board by transferring a solder paste by printing with a printed mask shape conforming to a pattern. With the currently used Sn-37Pb eutectic solder, the pattern of the circuit board and the pattern of the printing mask are generally identical.

Extensive research and development have been carried out for a substitute solder for conventional lead-tin compositions, such as Sn-37 (mass)% Pb (herein referred to as Sn-37Pb) eutectic solder. Such substitute solder includes mainly Sn-3Ag-0.5Cu, as well as compounds adding Bi or In, and Sn—Zn, Sn—Sb, Sn1 Ag-57Bi, etc. Unfortunately the substitute Pb-free solder suffers from poor wetting characteristics and melt-separation compared with the Sn-37Pb eutectic solder.

### BRIEF SUMMARY OF THE INVENTION

When the electrodes of a circuit board are supplied with solder, for example, by a transfer (printing) method, and an electronic part (semiconductor device) is connected to the circuit board by pressing or scrubing the electronic part (semiconductor device) to the board, a problem arises of unnecessary ball formation on the side of the board electrodes after reflow. Further, when supplying Pb-free solder to the electrodes of a board, in place of the lead-containing solder, the problem arises frequently. These undesired solder balls can move on the board and cause electrical short-circuits, lowering the reliability of the electronic device.

This invention provides a circuit that does not form unnecessary solder balls when a semiconductor device or other component is mounted on a board. Further the invention provides a circuit board that does not form unnecessary solder balls when using Pb-free solder. The invention enables electronic devices of higher reliability having a solder joints that do not form solder balls. This increases the yield in the manufacture of electronic devices.

According to one aspect of the invention, a circuit board includes a first electrode and a second electrode connected with respective electrodes of a chip, and a first insulating film formed with openings provided at respective positions corresponding to the first and second electrodes, in which the openings in the first insulating layer are shaped such that the first insulating layer does not cover a region below the chip in at least the circumferential edges of the first and second electrodes.

According to another aspect of the invention, a circuit board includes a first electrode and a second electrode connected with respective electrodes of a chip, and a first insulating film formed with openings provided at respective positions corresponding to the first and second electrodes, in which, in a region below the chip, a first gap portion is provided between the first electrode and the first insulating layer and a second gap portion is provided between the second electrode and the first insulating layer.

According to another aspect of the invention, a method of manufacturing a circuit board having a first electrode and a second electrode to be connected with respective electrodes of a chip and wiring connected electrically with the first and second electrodes, includes the steps of forming the wiring and the first and second electrodes on a board; and forming a first insulating layer on the board with openings provided at respective positions corresponding to the first and second electrodes, in which the openings are formed such that the first insulating layer does not cover at least a region below the chip on the peripheral edges of the first and second electrodes.

### BRIEF DESCRIPTION OF THE DRAWINGS

Other objects and advantages of the invention will become apparent from the following description of embodiments with reference to the accompanying drawings in which:

FIG. 1, including FIGS. 1a, 1b and 1c, is a diagram showing an electrode structure of typical circuit board and formation of an unnecessary solder ball;

FIG. 2a is a top view of chip electrodes mounted to the electrodes of a circuit board;

FIG. 2b is a cross-sectional view of FIG. 2a;

FIG. 3 is a top view of a large size chip mounted to the electrodes of a circuit board;

FIG. 4 is a top view of a chip of a 4-electrode structure mounted to the electrodes of a circuit board;

FIG. 5 is a top view of a semiconductor devices having a peripheral electrode structure mounted to the electrodes of a circuit board;

FIG. 6 is a top view of an area array semiconductor device mounted to the electrodes of a circuit board;

FIG. 7 is a flow chart illustrating manufacturing steps in one implementation of this invention;

FIG. 8 is a photograph of an example of a circuit board according to this invention; and

FIG. 9 is an enlarged view of the circuit board of FIG. 8.

### DETAILED DESCRIPTION OF THE INVENTION

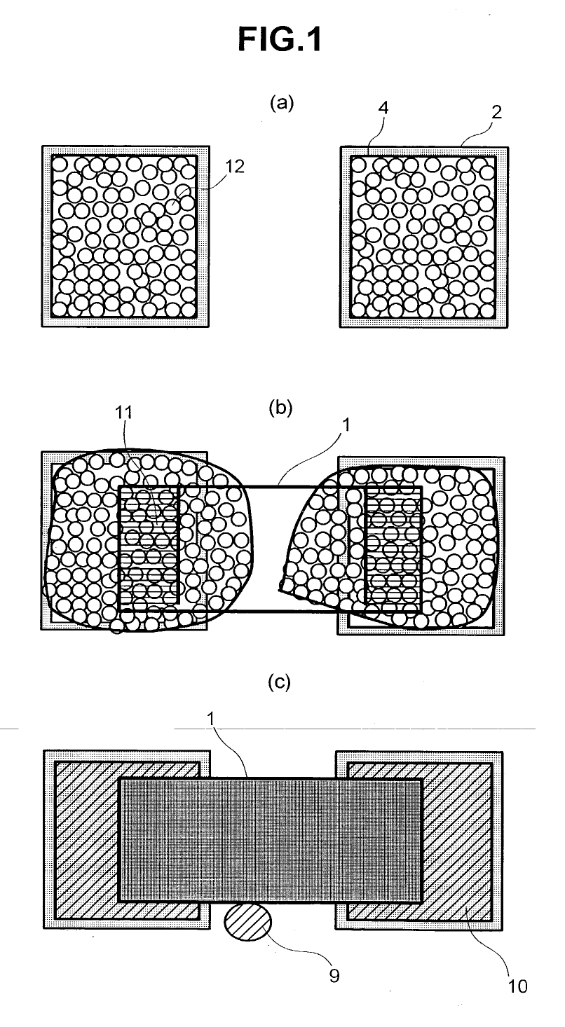

FIG. 1 illustrates unnecessary solder residue 9 (in the form of a ball) formed when an electronic part (chip) 1 is solder bonded to electrodes 2 (also referred to as a wiring pattern 2) of a circuit board using a solder paste. Specifically, FIG. 1 a shows solder paste 12 supplied to electrodes 2 of a circuit board by printing using a mask. FIG. 1 a illustrates the printing-coating size of a solder paste and the size of an opening 4 of a first solder resist are made substantially identical with each other and solder is supplied in the opening. In this case, it is preferred that the mask pattern and the region of the solder supplied by printing from the mask are made slightly smaller than opening portion 4 of the solder resist and inward of the opening portion. The entire electrode 2 (terminal 2) is wetted by the sag of the paste and some wetting is spread by the solder in a reflow furnace.

To make a mask print pattern identical in size with opening 4 of the solder resist, positional misalignment between the supplied solder portion and solder resist opening 4 occurs at a portion where positional misalignment between the board and the printing mask is large. When the solder paste sags (spreads excessively), it cannot return to board electrode 2, thereby causing a separate solder ball residue 9. A mask pattern identical with a mask pattern used for standard Sn—Pb eutectic solder may be used.

FIG. 1b illustrates a chip 1 of a 2-electrode structure having a metallized electrode (for example, Ni/Sn plating) (1608 chip) mounted on electrode 2. As shown in FIG. 1b, when the connection of a typical 2-electrode structure is connected to the electrodes of a substrate or board, the electrodes of the electronic part are connected to the inside of the facing board electrodes 2. That is, the electrodes of chip 1 are connected to board electrodes 2 at a position slightly inside board electrodes 2. Accordingly, when electronic part 1 is mounted on board electrodes 2 by moving it to the back of the electrode surface of the electronic part, the solder paste flows out below the chip leads, that is, between the facing board electrodes.

FIG. 1c shows where an undesired solder ball 9 of 100 to 500 μm in diameter has formed near the chip after the chip 1 was allowed to pass through a reflow furnace (at a temperature of about 220 to about 260° C.) with the chip mounted on board electrodes 2. Chip 1 is connected to board electrodes 2 through a solder connection portion 10. Unnecessary solder ball 9 was caused because part of the solder supplied to electrode 2 extended to a portion where it was below the chip 1 and electrode 2 was not present. Thus the solder could not return to the board electrode (pad) after reflow.

In particular, if lead-free solder (e.g., Sn-3Ag-0.5Cu, melting point: 217 to 221° C.) is used, because it is less likely to wet spread on the board electrode (e.g., Cu electrode), it is necessary to increase the amount of solder supplied to the board electrode beyond the amount of currently used lead-containing solder. Accordingly, it has been found that when electronic part 1 is pushed against board electrode 2, the solder is liable to flow beyond the solder resist that surrounds the periphery of board electrode 2, thereby creating the undesired solder balls. Such solder balls 9 are formed even if lead-free solder is used that has compositions in which the amounts of Ag and Cu are slightly different from that noted above.

We have studied the shape of the printing mask for solder paste relative to electrodes 2 of the circuit board to prevent occurrence of the unnecessary solder ball or bridge. Consequently, we could prevent formation of the unnecessary balls under predetermined conditions. However, when the positional misalignment between the printing mask and the circuit board is large or when lead-free solder is used, it is difficult to completely prevent occurrence of the solder ball or solder bridging.

In view of the above, we have made a further study on a method that causes no formation of unnecessary solder balls even when there is some positional misalignment of the printing mask or when lead-free solder is used. As a result, occurrence of the unnecessary solder balls and formation of solder bridges can be prevented by improving the solder resist of the circuit board. This will be explained below. In our tests 1005, 2125, 3216, 3225 type chips, etc. of different size were dealt with in the same manner as the 1608 chip, and significant effects were confirmed in the experiment, the 1608 chip is used herein as an example.

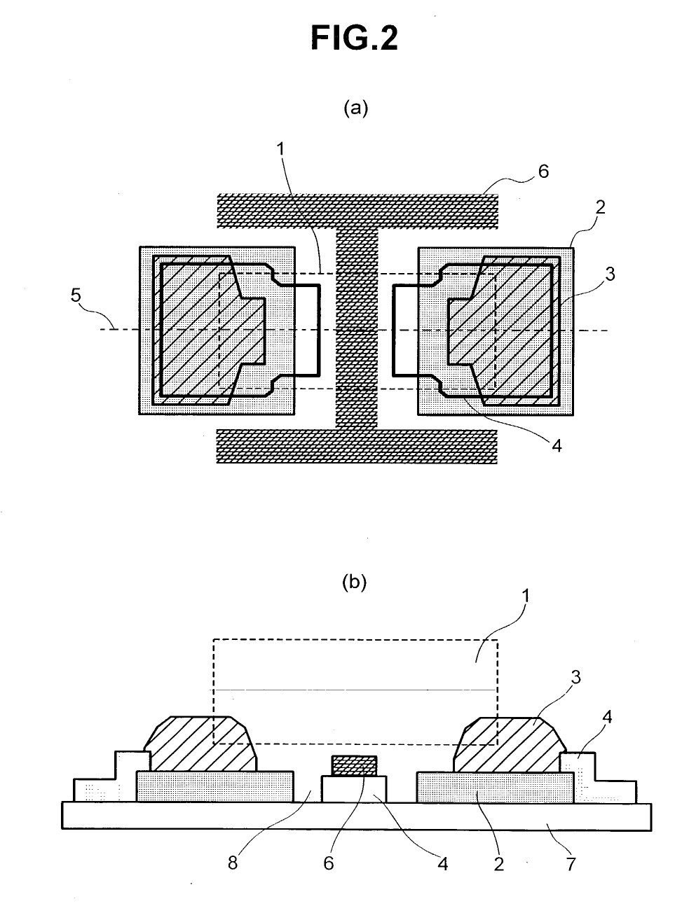

FIG. 2 illustrates a chip (electronic part) mounted on a circuit board as an example of this invention. FIG. 2a is a top view showing the relation between a chip (1608 chip) 1, an electrode 2 (Cu pad pattern region 2) of the circuit board, a solder paste supply region 3, a first solder resist region 4 and a second solder resist region 6 (also termed a seal resist). FIG. 2b is a cross-sectional view taken along a central line 5 of FIG. 2a. While the first insulating layer (first solder resist) was formed to cover the periphery of the electrode portion of the board in the instant structure, a portion of the electrode portion is not covered by first solder resist 4 in this example as shown in FIG. 2a.

Because a portion of board electrode 2 (Cu pad) is not covered with the solder resist, a gap 8 (sometimes referred to as a reservoir) is defined between electrode 2 and first solder resist 4. Gap 8 prevents the sag of the solder paste and prevents the solder from flowing out on the side of electrode 2. Because the solder paste stays within the range of board electrode 2 even when it flows out to gap 8, when the solder supplied to the electrode is melted, the solder flowing into reservoir 8 is also attracted to the solder on board electrode 2 and is integrated therewith by the surface tension of the solder, and no solder ball is formed.

Once the electronic part is mounted, a portion of the solder supplied to the board electrode may be present in reservoir 8 to prevent solder from flowing out. That is, as long as the solder supplied to the board electrode does not flow beyond reservoir 8, neither an unnecessary ball 9 nor a short circuit between the electrodes is formed.

Further, it is desirable that the region of electrode 2 situated below the chip 1 not be covered with the first solder resist. Since the chip having two or more electrodes is usually mounted inside the electrode pad, the solder paste inside (below the chip) is crushed, tending to allow the solder to flow out upon reflow. Accordingly, when the chip has two electrodes as shown in FIG. 2, the flowing out and bridging of the solder can be prevented by locating gap 8 inside the adjacent board electrodes 2, preferably near the central portion.

It will be apparent that gap 8 may be disposed not only inside the adjacent electrode pads but also on the lateral side of the region where the chip is mounted. Further, while the shape of the first solder resist has been explained as being extended beyond board electrode 2 only at one position, it may also be extended at a plurality of positions. Of course the shape of board electrode 2 need not be rectangular, but may be any desired configuration.

Next is a description of the shape of a mask for supplying the solder to the circuit board and the shape of the supplied solder. As can be seen from the coated shape of the solder in FIG. 2, the solder printing metal mask and the solder supplied are formed as a convex pattern relative to the opposing electrode. It is desirable that the amount of solder supplied to the electrodes of the board associated with chip 1 be progressively decreased toward the opposing direction of electrodes 2, so that it has a convex shape when the shape of the solder on board electrode 2 is viewed from the upper surface of the board. That is, it is designed such that the solder is collected to the central portion and collected in reservoir 8.

When the solder is supplied using a concave metal mask, the solder is divided to both sides relative to the central axis of the concave shape and the balance between both sides is worsened causing a tombstone phenomenon. In this situation, the balance is lost and the chip rotates toward one of the sides. Thus, it has been found that a generally convex shape in which the solder supplied by the metal mask is located at the central portion of the chip is preferred. In particular, a convex shape with the top end being parallel at the end is preferred.

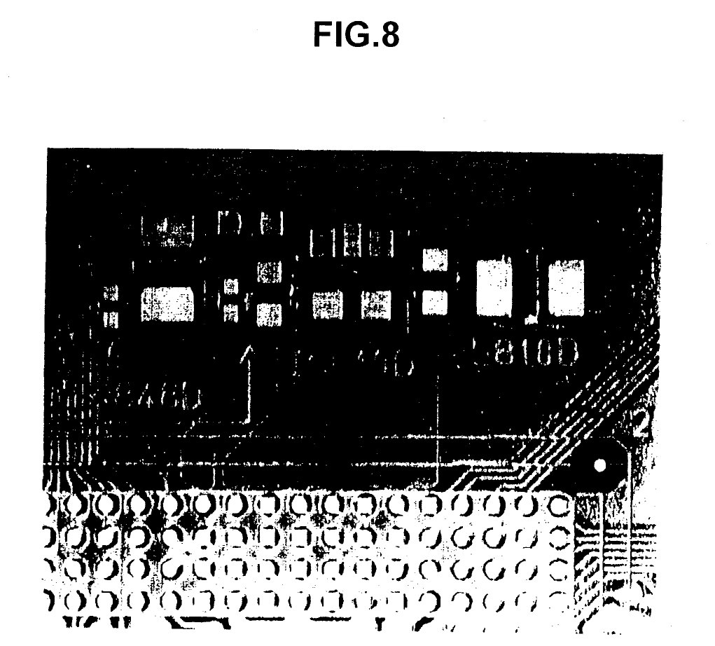

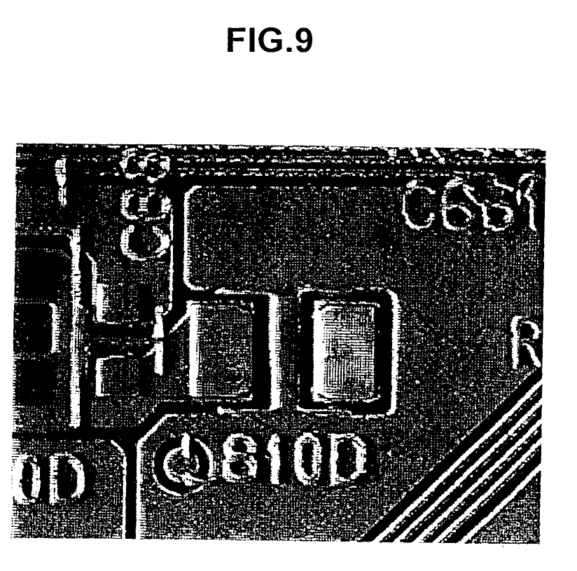

A second insulating layer 4 (second solder resist 4) is now described. As shown in FIG. 2, it is desirable to form a second solder resist on the first solder resist at least in a region where the electronic part is mounted. FIGS. 8 and 9 are views showing circuit boards in which the first and the second solder resists were formed in an experiment. FIG. 9 is an enlarged view of a region (at the periphery of 810 D) in which a chip is mounted in the circuit board of FIG. 8. A board electrode associated with a 2-electrode chip is present at the central portion, of FIG. 9, in which solder resist is formed. A first solder resist is formed in the circuit board. A second resist is formed between electrodes associated with the 2-electrode chip. A mark, for example, 810D indicated below the board electrode is an identification mark for the electronic part. The second solder resist can prevent the solder paste from flowing beyond reservoir 8 for solder loss prevention and to prevent formation of a solder bridge.

FIG. 2 illustrates the second solder resist in the shape of an H configuration. Usually, when the chip is moved on mounting of the chip, the supplied solder paste is extended as far as a portion where the electrode terminal is not present. This forms unnecessary solder balls 9 under the effect of surface tension on reflow. This phenomenon is also liable to occur on the lateral region of chip 1. Accordingly, when the second solder resist is formed below the chip and on the lateral periphery of the chip, the solder extending from the board electrode on reflow is within a range that it can return to the board electrode, and thus prevent formation of the unnecessary solder balls and subsequent short circuit between the electrodes. The second solder resist may also be formed on the entire periphery of board electrodes 2.

Next, the shape of circuit board 1 is described. The thickness of board electrode 2 (Cu pad) of the circuit board is about 40 μm, the thickness of the first insulating layer (first solder resist) is about 30μ 5 μm, the thickness of the second insulating layer (second solder resist) is 15μ 5 μm and the printed coating thickness of the solder is 150 μm. The upper limit of the thickness of the second solder resist is determined such that the second solder resist is not in contact with the bottom of mounted chip 1. The distance (T) from the mounting surface (upper surface) of board 7 to the bottom of chip 1 has to be greater than the sum of the thickness (T1) of the first resist and the thickness (T2) of the second resist (T>T1+T2). T is determined in accordance with the thickness (T3) of board electrode 2 (Cu patter electrode) and the amount of solder paste (height: T4). While the thickness of the second solder resist cannot be generally determined beforehand in view of the effect, for example, of the amount of solder to supply to the electrode and the thickness of the board electrode 2, it is preferably from ⅓ to 3/2 the thickness of the first solder resist.

Further, the distance between the first solder resist below chip 1, that is, traversing the opposing electrodes and the second resist end was about 0.1 to 0.2 mm. Further, the distance between the side of the electrode end and the side of the protruding end of the first solder resist was about 0.2 to 0.3 mm. The unnecessary solder ball 9 and the solder bridge were not formed within this range.

The method of manufacturing the circuit board according to this embodiment is described next. At first, a wiring pattern (including electrodes) is formed on a board or substrate by printing or photolithography. The board may be any well known board, and can includes a ceramic board or a printed board.

Next, a first solder resist provided at an opening of a board electrode is formed by using an insulative material. The first solder resist is formed by printing or photolithography. A solder resist can be formed at low cost by printing, whereas a solder resist coping with a wiring pattern having a narrow pitch distance can be formed by photolithography. It is apparent that the shape of the first solder resist is formed not to cover a portion of electrode 2 as explained previously.

After forming the first solder resist, an identification mark (for example, the number of the chip) is sealed at a position corresponding to an electronic part (chip) mounted on the substrate. A circuit board is formed by the steps described above. Then a second solder resist (seal resist) may optionally be formed. The second solder resist is also formed by printing or photolithoetching. The first and second solder resists are formed by any of the combinations of: (1) photolithoetching and photolithoetching, (2) photolithoetching and printing, (3) printing and photolithoetching and (4) printing and printing.

When forming the second solder resist by a photolithoetching method as in (1) or (3) above, since the second solder resist can be formed finely and accurately, a fine electrode pattern can be created. However, an etching solution must be selected that will not damage the first solder resist in the step of forming the second solder resist. In particular, in method (1) above, the material for the insulating layer forming the first and second solder resists must be suitably selected.

On the other hand, for (2) or (4), there is no requirement for stringent selection of the etching solution and the solder resist material used for the second solder resist. In addition, the thickness of the second solder resist can be changed freely. However, unlike photolithography, in printing, there is an additional requirement of providing a printing mask, and fine fabrication is difficult. Thus, when the chip electrode is small printing is difficult. In FIG. 2, the solder resist between the Cu patterns is formed in two steps but the second resist is not always necessary. In other words, the second resist is formed to further prevent the solder paste from flowing beyond the first resist.

In the foregoing, it has been explained that the sealing step of forming the identification mark for chip 1 and a step of forming the solder resist are separate steps. However, the identification mark and the second solder resist can be formed in a single step by making the material used for the second solder resist identical with the material used for sealing. Thus, it is not required to provide an additional step of forming the second solder resist to further prevent solder flow, making manufacture of a wiring substrate of high reliability at low cost possible. We carried out curing of the first solder resist at 140 to 160° C. for 1 hr and then cured the second solder resist with UV-rays at 30° C., at 900-1500 mj/cm2 for 30 sec to form a circuit board.

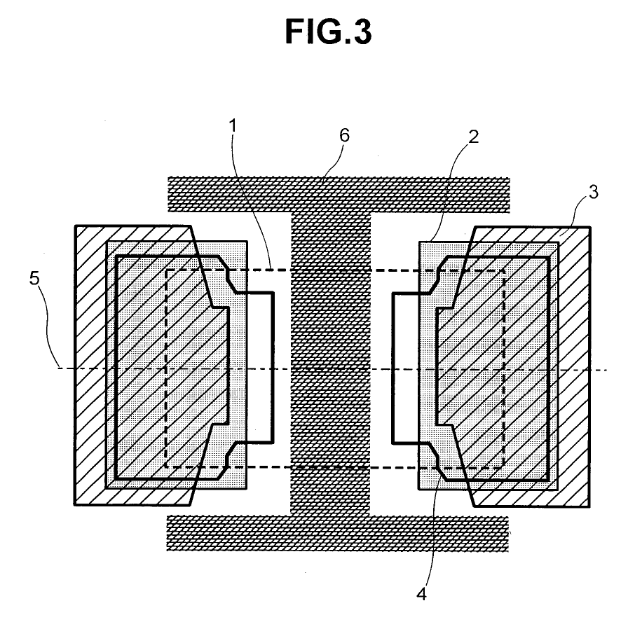

FIG. 3 is a top view of a model when the invention is applied to a 3225 large-scale chip. For a small chip, it is sufficient for the coating range of the second resist (seal resist) on the lateral side of the chip to reach the chip end. For a large chip, the coating width is made wide, so that a position at the end where the solder tends to sag is within the resist coating region. Further, the distance between the first solder resist below the chip, that is, traversing the opposing electrodes and the second resist end is desirably about 0.1 to 0.2 mm irrespective of the size of the chip.

Accordingly, in a large-sized chip, the width of the second resist below the chip is necessarily wide. The resist may be formed back-to-back in a rectangle with one side open, instead of the H configuration as shown in FIG. 3. A large-sized chip is configured such that a large amount of solder is applied on the back margin of the electrode (Cu pattern) because of the need to attach a sufficient amount of solder. We found that no unnecessary residue ball formed even when a large amount of solder was used to coat the back portion of the electrode.

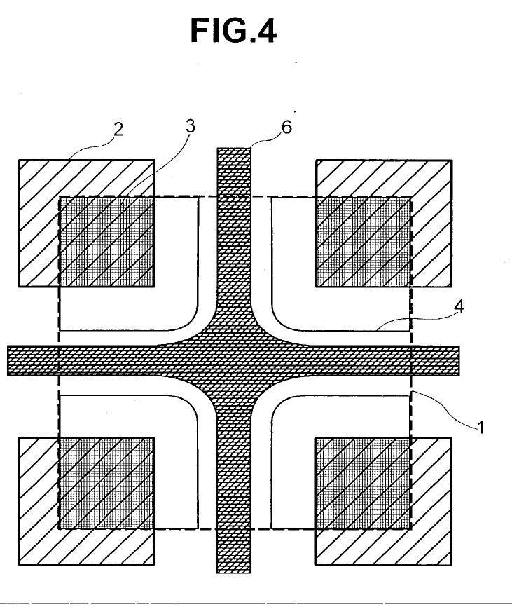

The effect of preventing the occurrence of the balls and preventing the occurrence of bridging have been confirmed for chips from small to large sizes such as 1005, 2125, 3216 and 3225 chips. In the instant method, probability of the large solder ball residue is lower in with Sn—Pb eutectic solder compared to Pb-free solder but the occurrence took place under poor conditions. That is, we found that the use of the circuit board according to this invention is effective in preventing the occurrence of unnecessary solder balls and preventing a short circuit between electrodes not only in Sn—Pb eutectic solder but also in lead-free solder. In the foregoing, the explanation has been made of a chip having two electrodes, but the invention is not restricted thereto and may also be applied to a board, for example, on which a chip having four electrodes is mounted as shown in FIG. 4, whereby similar effects can be obtained.

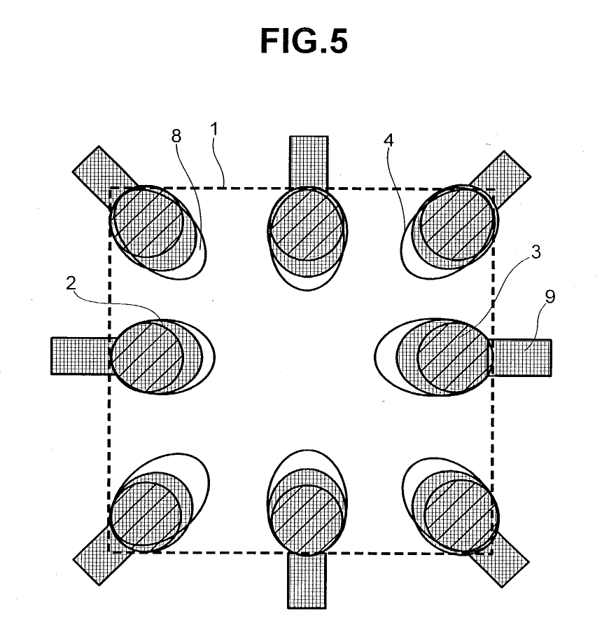

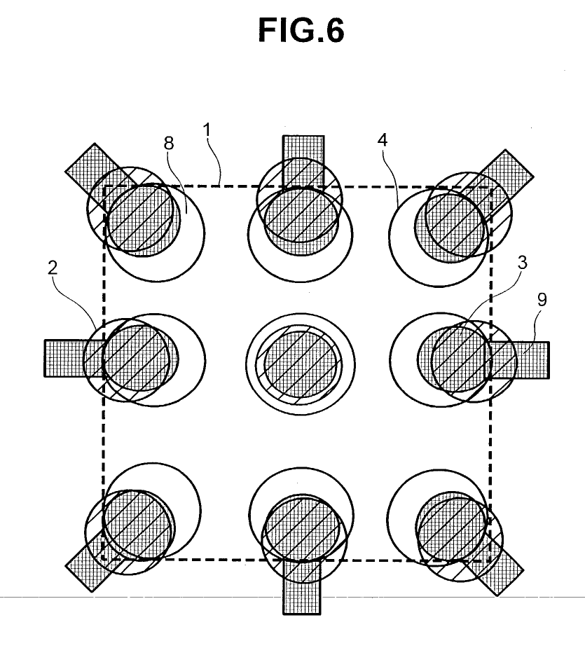

Further, the invention can be applied not only to the chip, but also to a board for mounting a semiconductor device, as shown in FIGS. 5 and 6. FIG. 5 illustrates the shape of a first solder resist of a board on which a semiconductor device having peripheral electrodes is mounted, and FIG. 6 illustrates the shape of a first solder resist of a board on which a semiconductor device having an area array type electrode structure is mounted.

In a chip or a semiconductor device which has many electrodes, openings in the first solder resist formed correspondingly to the electrodes of the board may not always be identical with each other. For example, since unnecessary solder balls are liable to form below the semiconductor device as shown in FIG. 5, it is desirable that the first solder resist be formed such that a large solder reservoir is formed at the central portion of the semiconductor device.

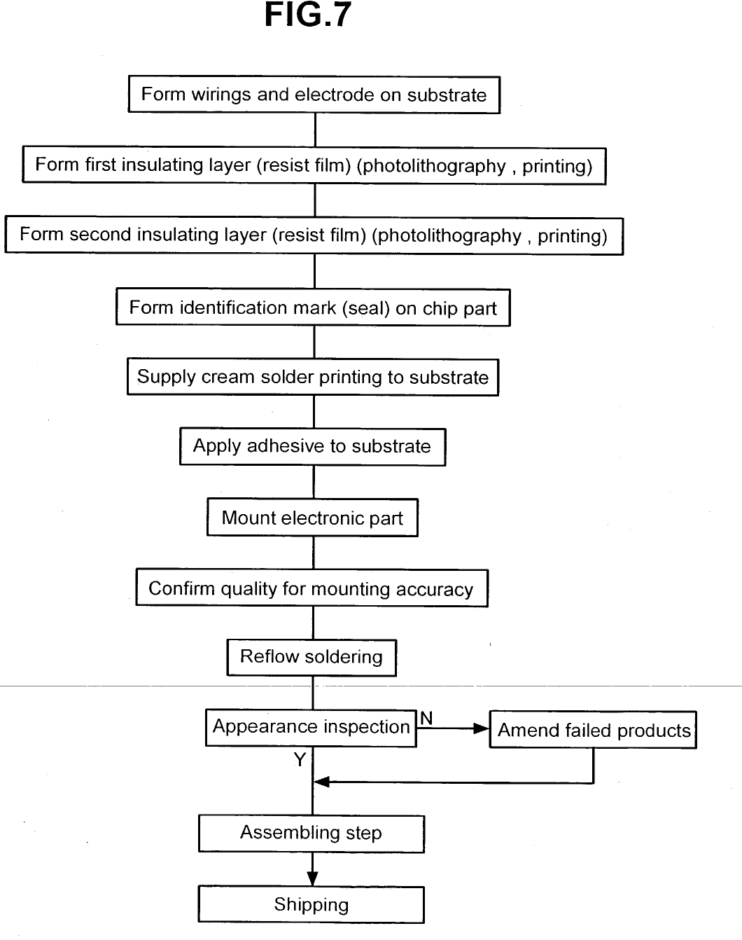

Semiconductor devices and chips are mounted on the circuit board described above to form an electronic device or product. FIG. 7 illustrates a flow chart for the steps of manufacturing such a product. In this case, the circuit board used for the electronic device has the shape of the first solder resist, as explained above, at least for the electrodes corresponding to the chip. It will be apparent that the shape of the second solder resist, also explained above, may also be used. Further, the details of the example for the circuit board explained above may also be adopted for the board electrode or for the first and second solder resists for all the electronic parts (chips, semiconductor devices) to be mounted. In electronic equipment according to this invention, since formation of unnecessary residual solder and formation of a solder bridge on the circuit board can be prevented, yields of the electronic devices are improved and reliability is improved.

The invention has been described specifically with reference to preferred embodiments but it will be apparent to those skilled in the art that the invention is not restricted only to the embodiments described above but can be modified within the scope and spirit of the invention.

Typical aspects disclosed in the embodiments described above are as follows:

(1) A circuit board including a first electrode and a second electrode connected to the respective electrodes of a chip, and a first insulating film formed with openings provided at positions corresponding to the first and second electrodes is characterized in that the openings in the first insulating layer are shaped such that the first insulating layer does not cover a region below the chip, at least at the circumferential edges of the first and second electrodes.

(2) The circuit board described in (1) is characterized by having a first gap portion between the first electrode and the first insulating layer, and a second gap portion between the second electrode and the first insulating layer, in a region below the chip.

(3) A circuit board including a first electrode and a second electrode connected to the respective electrodes of a chip, and a first insulating film formed with openings provided at positions corresponding the first and second electrodes is characterized by a first gap portion between the first electrode and the first insulating layer, and a second gap portion between the second electrode and the first insulating layer.

(4) The circuit boards described in (2) and (3) are characterized by the first second gap portions being provided to prevent a short circuit between the first and second electrodes.

(5) The circuit boards described in item (2) or (3) are characterized by the first and e second gap portions being provided to keep solder from protruding out of the first and second electrodes.

(6) The circuit boards described in (2) and (3) are characterized by a second insulating layer in a region on the first insulating layer between the first and second electrodes.

(7) The circuit board described in (6) is characterized by a second insulating layer formed on the lateral sides of the first and second electrodes.

(8) The circuit board described in (6) is characterized by the material for the first insulating layer being different from the material for the second insulating layer.

(9) The circuit board described in (6) is characterized by the second insulating layer having a height such that it is not in contact with the lower surface of the chip when the chip is mounted.

(10) The circuit boards described in (1) and (3) are characterized by having a first solder paste on the first electrode and a second solder paste on the second electrode, both the first and second solder pastes are a lead-free solder material.

(11) The circuit boards described in (1) and (3) are characterized by having a first solder paste on the first electrode and a second solder paste on the second electrode, the first solder paste and the second solder paste are formed in a shape such that each protrudes in a direction so that both face each other below the chip.

(12) A method of manufacturing a circuit board having first and second electrodes connected to respective electrodes of a chip and wiring electrically connected to the first and the second electrodes is characterized by the following steps: forming the wiring and the first and second electrodes on a board; and forming a first insulating layer on the board with openings provided at positions corresponding to the first and second electrodes, the openings formed such that the first insulating layer does not cover a region below the chip at least at the peripheral edges of the first and second electrodes.

(13) A method of manufacturing a circuit board described in (12) further including a step of forming a second insulating layer at a region on the first insulating layer between the first and second electrodes.

(14) A method of manufacturing a circuit board described in (13) is characterized by the first and second insulating layers being formed by different methods.

(15) A method of manufacturing a circuit board described in (13) is characterized by the first insulating film and being formed by a photolithoetching method.

(16) A method of manufacturing a circuit board described in (13) is characterized by the first insulating film being formed by a photolithoetching method and the second insulating layer being formed by a printing method.

(17) A method of manufacturing a circuit board described in s (13) is characterized by the first insulating film being formed by a printing method and the second insulating layer being formed by a photolithoetching method.

(18) A method of manufacturing a circuit board described in (13) is characterized by the first insulating film and the second insulating layer being formed by a printing method.

(19) A method of manufacturing a circuit board described in (13) is characterized by an identification number for the electronic part mounted on the board being formed on the board in the step of forming the second insulating layer.

(20) An electronic device is characterized in which the chip is mounted to a circuit board described in any one of aspects (1) to (19).

(21) The electronic device described in 20 is characterized by having another semiconductor mounted to the circuit board.

The present invention provides an electronic circuit board in which a solder paste is printed on a circuit board formed with a predetermined wiring pattern electrode. This electronic circuit board has an electrode structure for use in solder paste coating of a circuit board which is characterized by solder resist openings formed not only on the wiring pattern, but also partially on the outside of the wiring pattern, extending in a convex shape such that both of the electrodes are opposed to each other.

Further, the present invention provides an electronic circuit board in which a solder paste is printed on a circuit board formed with a predetermined wiring pattern electrode. This electronic circuit board has an electrode structure for use with lead-free solder paste coating of a circuit board characterized by solder resist openings that are formed on the wiring pattern and formed partially on the outside of the wiring pattern being extended in a convex shape such that both of the electrodes oppose each other. In addition, the central portion between the electrodes and both lateral sides of the chip are coated with a sealing resin or the like in an H-like configuration or in a back-to-back rectangle with one side open, both lateral sides of the chip being coated as far as the end of the chip at the maximum. An electronic device that uses this electronic circuit board is also provided.

Further, the above electronic circuit board and electronic device may have an electrode structure for lead-free solder paste coating of a circuit board characterized by the solder being shaped by a metal mask formed into a convex shape in the direction of the opposing electrode, or shaped in an inverted V at the central portion, or having a protruding shape with a radius of curvature, and the wiring pattern over which the solder wet spreads after printing expanding to the periphery of the solder shape. The advantages of the present invention include elimination of solder balls, even when lead-free solder is used, higher reliability, and improved yields.

What is claimed is:

1. A circuit board comprising:
a first electrode and a second electrode connected with respective electrodes of a chip; and
a first insulating film formed with openings at respective positions corresponding to the first electrode and the second electrode; and
wherein the openings in the first insulating layer have a shape in which the first insulating layer does not cover a region below the chip in at least the circumferential edge of the first electrode and the circumferential edge of the second electrode.

2. A circuit board as in claim 1 wherein, in a region below the chip, a first gap portion is provided between the first electrode and the first insulating layer and a second gap portion is provided between the second electrode and the first insulating layer.

3. A circuit board comprising:
a first electrode and a second electrode connected with respective electrodes of a chip; and
a first insulating film formed with openings being provided at respective positions corresponding to the first electrode and the second electrode;
wherein, in a region below the chip, a first gap portion is provided between the first electrode and the first insulating layer and a second gap portion is provided between the second electrode and the first insulating layer.

4. A circuit board in claim 2, wherein the first gap portion and the second gap portion are provided so as to prevent a short circuit between the first electrode and the second electrode.

5. A circuit board in claim 2, wherein the first gap portion and the second gap portion are provided so as to reserve solder protruding out of the first electrode and the second electrode.

6. A circuit board in claim 1, wherein a second insulating layer is provide at a region on the first insulating layer and between the first electrode and the second electrode.

7. A circuit board in claim 6, wherein the second insulating layer is formed also on the lateral sides of the first electrode and the second electrode.

8. A circuit board in claim 6, wherein the material for the first insulating layer is different from the material for the second insulating layer.

9. A circuit board in claim 6, wherein the second insulating layer has a height such that it is not in contact with the lower surface of the chip when the chip is mounted.

10. A circuit board in claim 1, wherein a first solder paste is provided on the first electrode and a second solder paste is provided on the second electrode, both the first solder paste and the second solder paste being lead-free solder material.

11. A circuit board in claim 1, wherein a first solder past is provided on the first electrode and a second solder paste is provided on the second electrode, the first solder paste and the second solder paste are each in a protruding shape in the direction in which both face each other below the chip.

12. A method of manufacturing a circuit board having a first electrode and a second electrode connected with respective electrodes of a chip and wiring connected electrically with the first and the second electrode, the method comprising the steps of:
forming the wiring and the first and second electrodes on a board; and
forming a first insulating layer on the board with openings being provided at respective positions corresponding to the first and second electrodes;
wherein the openings are formed such that the first insulating layer does not cover a region below the chip in at least the peripheral edge of the first electrode and the peripheral edge of the second electrode.

13. A method of manufacturing a circuit board in claim 12 further comprising a step of forming a second insulating layer at a region on the first insulating layer and between the first electrode and the second electrode.

14. A method of manufacturing a circuit board in claim 13, wherein the first insulating layer and the second insulating layer are formed by different methods.

15. A method of manufacturing a circuit board in claim 13, wherein the first insulating film is formed by a photolithoetching method and the second insulating layer is also formed by the photolithoetching method.

16. A method of manufacturing a circuit board in claim 13, wherein the first insulating film is formed by a photolithoetching method and the second insulating layer is formed by a printing method.

17. A method of manufacturing a circuit board in claim 13, wherein the first insulating film is formed by a printing method and the second insulating layer is formed by a photolithoetching method.

18. A method of manufacturing a circuit board in claim 13, wherein the first insulating film is formed by a printing method and the second insulating layer is also formed by the printing method.

19. A method of manufacturing a circuit board in claim 13, wherein an identification number for the electronic part mounted on the board is formed on the board in the step of forming the second insulating layer.

20. An electronic device in which the chip is mounted on the circuit board in claim 1 by using a lead-free solder.
